(19) United States
(12) Patent Application Publication
(10) Pub. No.: US 2023/0243925 A1
(43) Pub. Date: Aug. 3, 2023

(54) NOISE JUDGMENT METHOD, NOISE JUDGMENT DEVICE AND PROGRAM

(71) Applicant: NIPPON TELEGRAPH AND TELEPHONE CORPORATION, Tokyo (JP)

(72) Inventors: Mayuko WATANABE, Musashino-shi, Tokyo (JP); Ryuichi TANIDA, Musashino-shi, Tokyo (JP); Hideaki KIMATA, Musashino-shi, Tokyo (JP)

(73) Assignee: NIPPON TELEGRAPH AND TELEPHONE CORPORATION, Tokyo (JP)

(21) Appl. No.: 17/927,766

(22) PCT Filed: May 29, 2020
(86) PCT No.: PCT/JP2020/021289

§ 371 Date: Nov. 25, 2022

(51) Int. Cl. G01S 7/48; G01S 17/89

(52) U.S. Cl. CPC G01S 7/4808; G01S 17/89

(57) ABSTRACT

A noise determination apparatus includes an acquisition unit and a determination unit. The acquisition unit acquires n-branch tree structure data. The n-branch tree structure data includes information on the presence or absence of a point for a divided region obtained by dividing, by an n-branch tree structure including a plurality of layers, a spatial region represented by point cloud data including information on a position of a point, and includes, for the divided region including only one point, a sign representing the point instead of information on a divided region in a layer lower than the divided region. The determination unit determines a point represented by the sign to be noise in a layer higher than a predetermined layer.

### TECHNICAL FIELD

The present invention relates to a noise determination method, a noise determination apparatus, and a program.

### BACKGROUND ART

Three-dimensional point cloud data is used for estimation of a structure such as a building. The three-dimensional point cloud data is coordinate data of a point cloud distributed three-dimensionally. In general, noise such as birds and dust is mixed in three-dimensional point cloud data measured by a sensor or the like. In order to perform more accurate estimation, it is necessary to remove the point cloud of the noise.

In order to eliminate noise, it is possible to provide a threshold for the distance between points and to remove outliers. However, it is difficult to appropriately set this threshold. On the other hand, in Geometry-based Point Cloud Compression (G-PCC) of Moving Picture Experts Group (MPEG), a point cloud is hierarchized by an octree and encoded (see, for example, NPL 1). The G-PCC has a function called a direct mode. This function is a technique of, when only one point exists inside a block of a certain layer, not hierarchizing the block thereafter, and encoding the relative position of the point.

### CITATION LIST

### Non Patent Literature

NPL 1: “Information technology-MPEG-I (Coded Representation of Immersive Media)-Part 9: Geometry-based Point Cloud Compression”, ISO/IEC DIS 23090-9, 2019.

### SUMMARY OF THE INVENTION

### Technical Problem

It is conceivable that a target for which information such as a building or a feature is desired to be acquired is often expressed by continuous points, whereas a point having no point in the periphery is determined not to be a target for which information is desired to be acquired, such as a bird, and thus a point inside a block for which the direct mode is selected from the three-dimensional point cloud data is determined to be an outlier, and a point of the outlier is determined to be noise and removed. However, depending on the acquisition density and accuracy of the point cloud, almost all points near the lowermost layer may be selected by direct mode. In such a case, there is a case where appropriate noise determination cannot be performed.

In view of the above circumstances, an object of the present invention is to provide a noise determination method, a noise determination apparatus, and a program capable of accurately determining noise included in point cloud data.

### Means for Solving the Problem

An aspect of the present invention is a noise determination method, including: acquiring n-branch tree structure data, the n-branch tree structure data including information on presence or absence of a point for a divided region obtained by dividing, by an n-branch tree structure including a plurality of layers, a spatial region represented by point cloud data including information on a position of a point, and including, for the divided region including only one point, a sign representing the point instead of information on a divided region of a layer lower than the divided region; and determining a point represented by the sign to be noise in a layer higher than a predetermined layer.

An aspect of the present invention is a noise determination apparatus, including: an acquisition unit configured to acquire n-branch tree structure data, the n-branch tree structure data including information on presence or absence of a point for a divided region obtained by dividing, by an n-branch tree structure including a plurality of layers, a spatial region represented by point cloud data including information on a position of a point, and including, for the divided region including only one point, a sign representing the point instead of information on a divided region of a layer lower than the divided region; and a determination unit configured to determine a point represented by the sign to be noise in a layer higher than a predetermined layer.

An aspect of the present invention is a program for causing a computer to execute the above-mentioned noise determination method.

### Effects of the Invention

According to the present invention, it is possible to accurately determine noise included in point cloud data.

### BRIEF DESCRIPTION OF DRAWINGS

FIG. 1 is a diagram illustrating a sequence of point cloud processing in a management system.

FIG. 2 is a block diagram illustrating a configuration of a noise determination apparatus according to a first embodiment.

FIG. 3 is a diagram illustrating a parent block and child blocks of spatial region division used in the same embodiment.

FIG. 4 is a diagram illustrating partitioning of a spatial region including point cloud data used in the same embodiment.

FIG. 5 is a diagram illustrating an example of an octree used in the same embodiment.

FIG. 6 is a flowchart illustrating noise elimination processing of the noise determination apparatus according to the same embodiment.

FIG. 7 is a diagram illustrating an example of the noise elimination processing illustrated in FIG. 6.

FIG. 8 is a flowchart illustrating noise elimination processing of the noise determination apparatus according to a second embodiment.

FIG. 9 is a flowchart illustrating noise elimination processing of the noise determination apparatus according to a third embodiment.

FIG. 10 is a diagram illustrating an example of the noise elimination processing illustrated in FIG. 9.

FIG. 11 is a flowchart illustrating noise elimination processing of the noise determination apparatus according to a fourth embodiment.

FIG. 12 is a diagram illustrating an example of the noise elimination processing illustrated in FIG. 11.

FIG. 13 is a diagram illustrating a hardware configuration of the noise determination apparatus.

FIG. 14 is a flowchart illustrating noise elimination processing to which an existing technique is applied.

FIG. 15 is a diagram illustrating an example of the noise elimination processing illustrated in FIG. 14.

### DESCRIPTION OF EMBODIMENTS

Hereinafter, embodiments of the present invention will be described in detail with reference to the drawings.

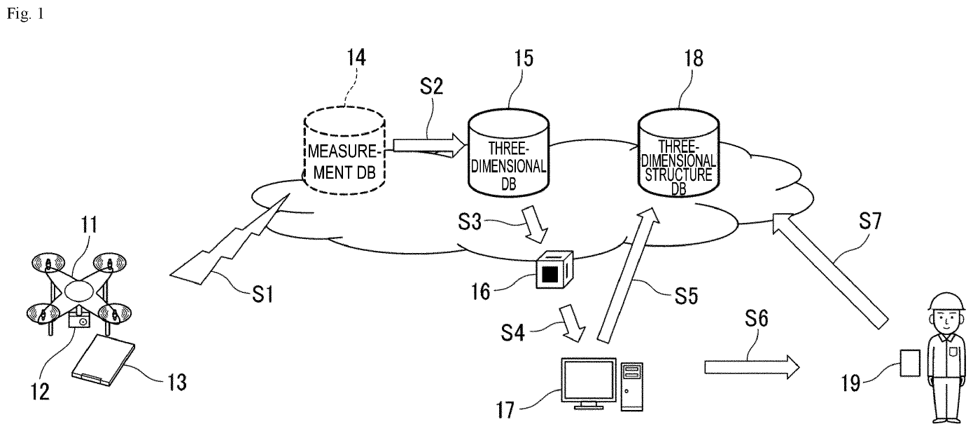

First, an example of point cloud processing will be described. FIG. 1 is a diagram illustrating a sequence of the point cloud processing in a management system. A light detection and ranging (LIDAR) 12 provided in a moving body 11 measures a district, a facility, or the like to be managed. The moving body 11 is, for example, a drone or a vehicle. The LIDAR 12 records measurement data indicating a measurement result in a memory 13. The measurement data recorded in the memory 13 is transferred to a measurement database (DB) 14 (step S1). The measurement data recorded in the measurement DB 14 is converted into point cloud coordinate attribute data and stored in a three-dimensional DB 15 (step S2). The point cloud coordinate attribute data includes three-dimensional point cloud data indicating a coordinate value of each point in three-dimensional coordinates, and attribute information of each point. The attribute includes, for example, information such as color. After the conversion, the measurement data stored in the measurement DB 14 is erased.

An information processing apparatus 16 acquires the point cloud coordinate attribute data recorded in the three-dimensional DB 15, compresses the three-dimensional point cloud data, and encodes and stores the compressed data (step S3). At this time, the information processing apparatus 16 eliminates noise by using the data used for compression/encoding. An analysis apparatus 17 acquires, from the information processing apparatus 16, the point cloud coordinate attribute data obtained by compressing and encoding the three-dimensional point cloud data from which the noise has been eliminated. The analysis apparatus 17 merges the acquired data and analyzes the three-dimensional structure (step S4). The analysis apparatus 17 writes the analyzed three-dimensional structure and the information on the hazardous location in the three-dimensional structure in a three-dimensional structure DB 18 (step S5). Further, the analysis apparatus 17 transmits a hazardous location and an inspection instruction of the hazardous location to a terminal device 19 of an operator (step S6). The operator performs inspection and operation according to the instruction transmitted from the analysis apparatus 17, and transmits a result report from the terminal device 19 (step S7). The three-dimensional structure DB 18 stores hazardous location prediction data based on the result report.

While the three-dimensional structure data is created as appropriate, the operator transmits an inspection or operation result report as needed. The three-dimensional structure DB 18 stores the latest three-dimensional structure data and a history of all hazardous location prediction data.

Hereinafter, a method and an apparatus for determining noise using information obtained in compression and encoding of the three-dimensional point cloud data will be described in detail.

### First Embodiment

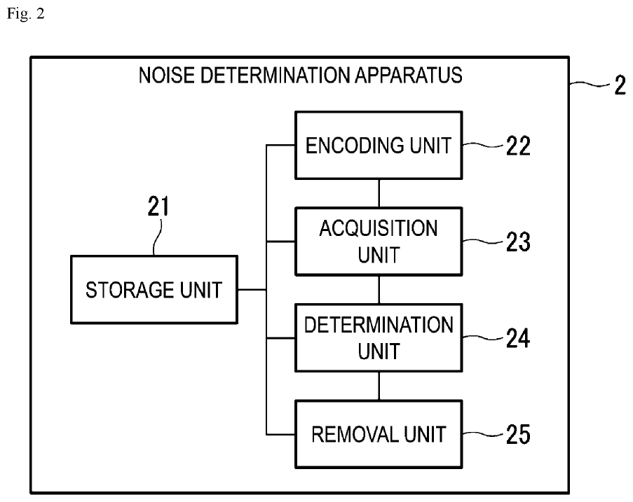

FIG. 2 is a block diagram illustrating a configuration of a noise determination apparatus 2 according to a first embodiment. The noise determination apparatus 2 is, for example, used as the information processing apparatus 16 of FIG. 1. The noise determination apparatus 2 includes a storage unit 21, an encoding unit 22, an acquisition unit 23, a determination unit 24, and a removal unit 25.

The storage unit 21 stores various data including point cloud data, tree structure data, and encoded data. The point cloud data is data of a set of coordinate values in which points exist in a predetermined spatial region. The tree structure data is data representing a divided space including points in the spatial region in an octree structure. The encoded data is data obtained by arithmetically encoding data having an octree structure.

The encoding unit 22 generates tree structure data from the point cloud data stored in the storage unit 21, and arithmetically encodes the tree structure data to generate encoded data. The encoding unit 22 writes the generated tree structure data and the encoded data into the storage unit 21.

The acquisition unit 23 acquires the tree structure data. That is, the acquisition unit 23 reads the tree structure data generated by the encoding unit 22 from the storage unit 21. Alternatively, the acquisition unit 23 may read tree structure data from an external device or may receive tree structure data transmitted from an external device. In these cases, the noise determination apparatus 2 may not include the encoding unit 22.

The determination unit 24 determines whether or not a point included in the point cloud data is noise based on the tree structure data acquired by the acquisition unit 23. The removal unit 25 removes a point determined to be noise by the determination unit 24 from one or both of the point cloud data and the tree structure data. The encoding unit 22 generates tree structure data from the point cloud data from which noise has been eliminated, and generates encoded data from the generated tree structure data. Alternatively, the encoding unit 22 generates encoded data from the tree structure data from which noise has been eliminated.

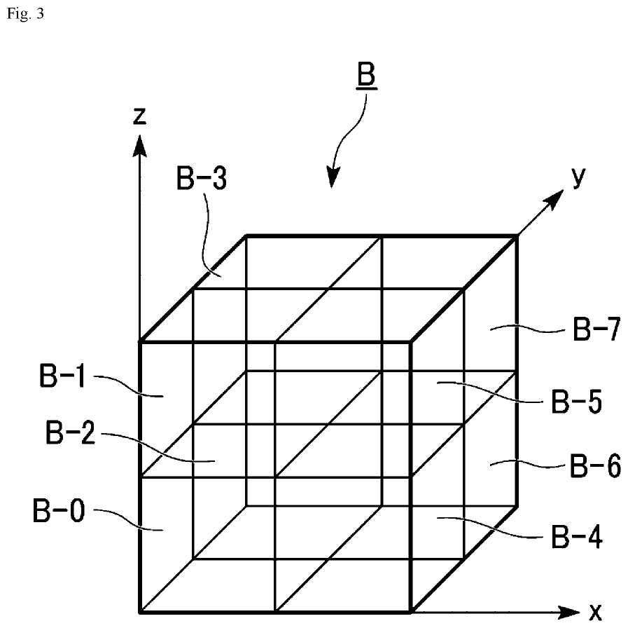

Generation processing of tree structure data by the encoding unit 22 will be described with reference to FIGS. 3 to 5. In the present embodiment, a coordinate value of each point included in the point cloud data is represented by a value of each component in xyz coordinates.

FIG. 3 is a diagram illustrating a parent block and child blocks in spatial region division. The encoding unit 22 divides a parent block B, which is a cubic space, into two parts in each of three directions (x-axis, y-axis, z-axis) orthogonal to each other. As a result, the encoding unit 22 generates eight cubic child blocks B-0 to B-7 from the parent block B.

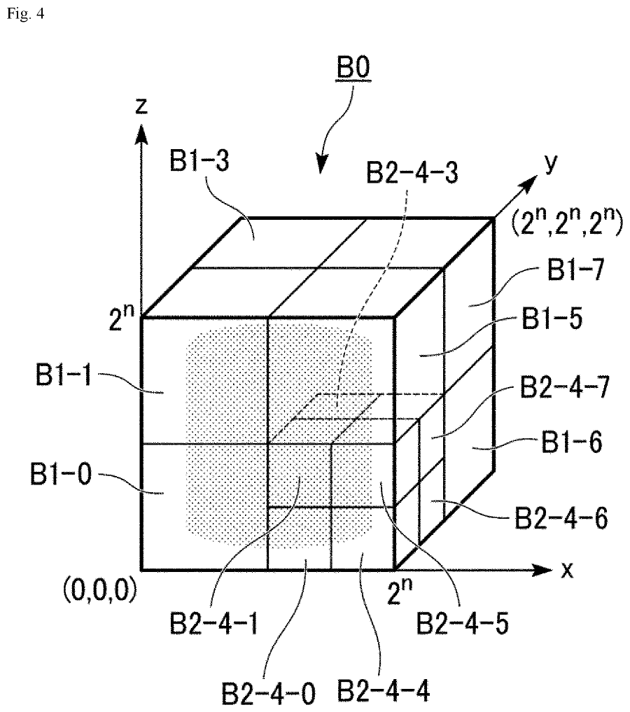

FIG. 4 is a diagram illustrating division of the spatial region including the point cloud data. First, the encoding unit 22 generates data of the block B0 including all the point cloud data. The block B0 is a cube having sides of 2ⁿ. In order to simplify the arithmetic processing, the encoding unit 22 translates the coordinates of the point cloud data such that the minimum value of each component of x, y, and z becomes 0. As a result, the coordinates of one vertex of the block B0 become (0, 0, 0). Each side of x=2ⁿ, y=2ⁿ, and z=2ⁿ of the block B0 does not include a point.

The encoding unit 22 performs spatial region division illustrated in FIG. 3 with the block B0 as a parent block, and generates blocks B1-0 to B1-7 which are eight child blocks. Next, the encoding unit 22 performs spatial region division illustrated in FIG. 3 using a block B1-i (i is an integer of 0 to 7) including two or more points among the blocks B1-0 to B1-7 as a parent block, and generates blocks B2-i-0 to B2-i-7 which are eight child blocks. The encoding unit 22 does not divide the block B1-i that does not include a point. Furthermore, the encoding unit 22 selects the direct mode and does not divide the block B1-i including only one point.

The encoding unit 22 performs the spatial region division illustrated in FIG. 3 using a block B2-i-j (j is an integer of 0 to 7) including two or more points among the blocks B2-i-0 to B2-i-7 as a parent block, and generates blocks B3-i-j-0 to B3-i-j-7 which are eight child blocks. The encoding unit 22 performs spatial region division using a child block including two or more points as a parent block, and repeats the above processing of selecting the direct mode for a child block including only one point a predetermined number of times or until the number of points included in the child block becomes 0 or 1. A child block generated by m-th (m is an integer of 1 or more) division is referred to as a block in an m-th layer.

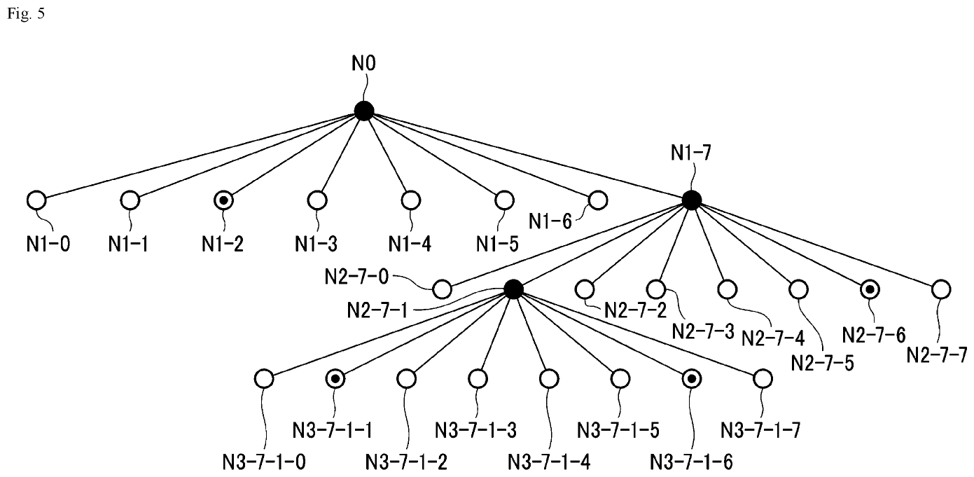

FIG. 5 is a diagram illustrating an example of an octree. The point cloud data is expressed by an octree corresponding to the divided three-dimensional space as illustrated in FIG. 4. The highest node NO corresponds to the block B0. The node NO is connected to eight nodes N1-0 to N1-7 in the first layer. A node N1-i corresponds to the block B1-i. In FIG. 5, nodes corresponding to blocks including a plurality of points are represented by black circles, and nodes corresponding to blocks not including points are represented by white circles. In addition, nodes corresponding to blocks for which the direct mode is selected, that is, blocks including only one point are represented by double circles with a black circle on the inner side. A node corresponding to a block including a point is described as a node including a point, and a node corresponding to a block not including a point is described as a node not including a point. In addition, a node corresponding to a block for which the direct mode is selected is described as a node for which the direct mode is selected.

The node N1-i including a plurality of points is connected to eight nodes N2-i-0 to N2-i-7 in the second layer. The node N2-i-j corresponds to the block B2-i-j. Since the encoding unit 22 does not divide the block B1-i not including a point or for which the block mode is selected, the node N1-i corresponding to the block B1-i is not connected to the node in the second layer. In FIG. 5, the nodes N1-0, N1-1, and N1-3 to N1-6 not including a point and the node N1-2 for which the block mode is selected are not connected to the node in the second layer. In addition, the node N1-7 including a plurality of points is connected to nodes N2-7-0 to N2-7-7 in the second layer. The nodes N2-7-0, N2-7-2 to 2-7-5, and 2-7-7 not including a point and the node N2-7-6 for which the block mode is selected are not connected to the node in the third layer. The node N2-7-2 including a plurality of points is connected to eight nodes N3-7-1-0 to N3-7-1- in the third layer.

The encoding unit 22 generates a node of the tree structure corresponding to the divided spatial region, as described above. For a node corresponding to a block including a plurality of points, the encoding unit 22 assigns a block value representing whether or not each of child blocks having the block as a parent block includes a point. That is, the encoding unit 22 assigns, to a node corresponding to a block including a plurality of points, a block value representing whether or not each node one level lower than the node includes a point. This block value is expressed as Equation (1). xₖ is a sign indicating whether or not a point is included in a k-th (k is an integer of 0 to 7) child block among eight child blocks. “1” indicates that a point is included, and “0” indicates that no point is included.

$$\begin{matrix}[ Math . 1 ] & \\ f ( {x}_{0} , {x}_{1} , {x}_{2} , {x}_{3} , {x}_{4} , {x}_{5} , {x}_{6} , {x}_{7} ) = {\sum }_{k = 0}^{7} {x}_{k} {2}^{k} & ( 1 )\end{matrix}$$

For example, in a case where only the blocks B1-2 and B1-7 among the child blocks of the block B0 include a point, the block value of the node corresponding to the block B0 is expressed as f (0, 0, 1, 0, 0, 0, 0, 1)=33. Furthermore, in a case where all the eight child blocks of a certain block include a point, the block value is expressed as f (1, 1, 1, 1, 1, 1, 1, 1)=255.

In this manner, the encoding unit 22 assigns a block value in which the position of a point is represented by a value from 0 to 255 by Equation (1) to a node corresponding to a block including a plurality of points. On the other hand, for the node corresponding to the block for which the direct mode is selected, the encoding unit 22 assigns a block value obtained by encoding the relative position of the point in the block, and adds information indicating that the direct mode is selected to the block value. The relative position is represented by, for example, a coordinate value in three-dimensional coordinates. The encoding unit 22 performs variable length coding on a block value assigned to a node corresponding to each block. The encoding is sequentially performed, for example, from the upper and left nodes illustrated in FIG. 5.

As described above, the encoding unit 22 converts the point cloud data into tree structure data in which a divided space including a point in a spatial region is represented by an octree structure. Then, the encoding unit 22 arithmetically encodes the tree structure data to generate encoded data.

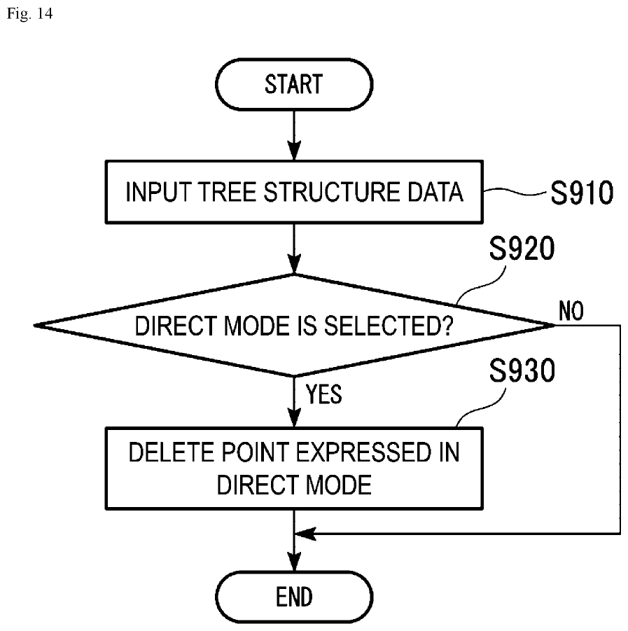

Next, processing in a case where the noise determination apparatus 2 performs noise elimination to which an existing technique is applied will be described. FIG. 14 is a flowchart illustrating noise elimination processing to which the existing technique is applied. The acquisition unit 23 performs the processing illustrated in FIG. 14 for each block generated by dividing the block B0 including the point cloud indicated by the point cloud data.

First, the acquisition unit 23 acquires tree structure data of a node corresponding to a block to be processed (step S910). The determination unit 24 determines whether or not the direct mode is selected for the block to be processed based on the tree structure data (step S920). When determining that the direct mode is not selected (step S920: NO), the determination unit 24 ends the processing for the block to be processed. On the other hand, when determining that the direct mode is selected (step S920: YES), the determination unit 24 determines a point included in the block to be processed to be noise. The determination unit 24 acquires information on the position of the point expressed in the direct mode from the tree structure data. The removal unit 25 deletes the point at the position acquired by the determination unit 24 from one or both of the tree structure data and the point cloud data (step S930).

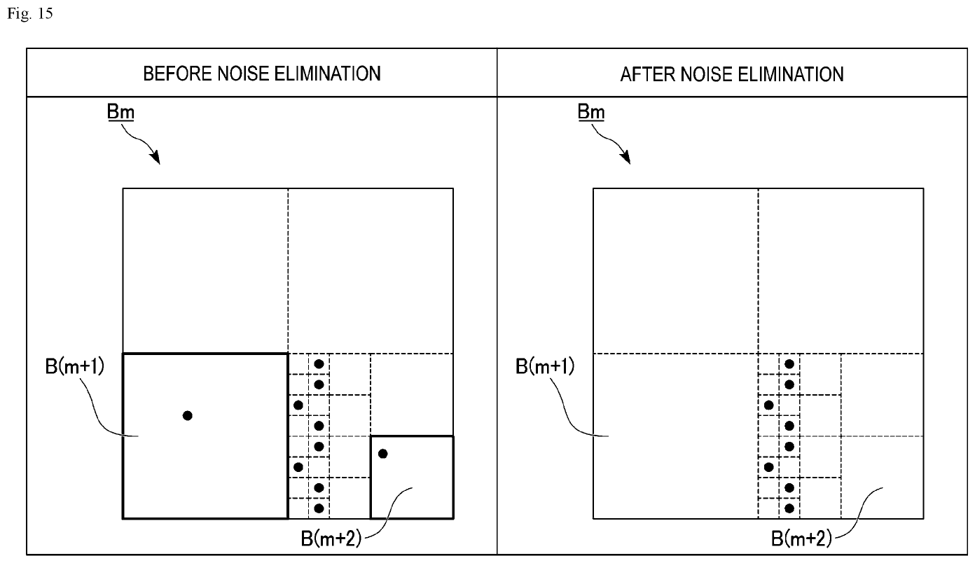

FIG. 15 is a diagram illustrating an example of the noise elimination processing illustrated in FIG. 14. In the drawing, for simplicity, each block obtained by dividing the spatial region is represented by a plane. A block Bm is a block in an m-th layer, the block B (m+1) is a block in an (m+1)-th layer, and the block B (m+2) is a block in an (m+2)-th layer. Before the noise elimination, the direct mode is selected for the block B (m+1) and the block B (m+2). The determination unit 24 determines points included in the blocks B (m+1) and B (m+2) to be noise. The removal unit 25 removes these points determined to be noise.

Depending on the acquisition density and accuracy of the point cloud, almost all points near the lowermost layer may be selected by direct mode. Therefore, there is a possibility that appropriate noise elimination cannot be performed in the processing illustrated in FIG. 14. Therefore, in a case where the direct mode is selected for a block in a predetermined layer or higher, the determination unit 24 determines a point included in the block to be noise.

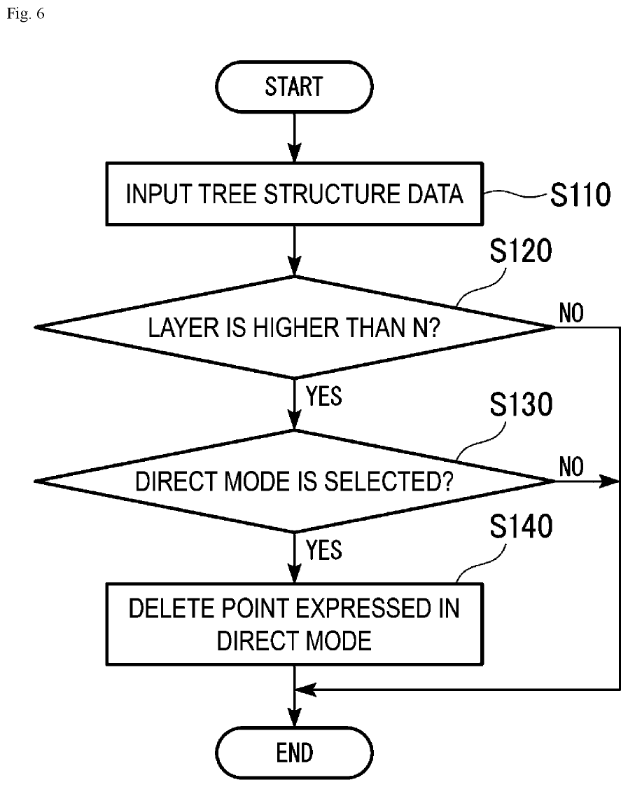

FIG. 6 is a flowchart illustrating the noise elimination processing of the noise determination apparatus 2. The acquisition unit 23 performs the processing illustrated in FIG. 6 for each block generated by dividing the block B0 including the point cloud indicated by the point cloud data.

First, the acquisition unit 23 acquires tree structure data of a node corresponding to a block to be processed (step S110). Based on the tree structure data, the determination unit 24 determines whether or not the layer of the block to be processed is higher than N (step S120). When determining that the layer of the block to be processed is N or less (step S120: NO), the determination unit 24 ends the processing for the block to be processed.

When determining that the layer of the block to be processed is higher than N (step S120: YES), the determination unit 24 determines whether or not the direct mode is selected for the block to be processed (step S130). When determining that the direct mode is not selected (step S130: NO), the determination unit 24 ends the processing for the block to be processed.

On the other hand, when determining that the direct mode is selected (step S130: YES), the determination unit 24 determines a point included in the block to be processed to be noise. The determination unit 24 acquires information on the position of the point expressed in the direct mode from the tree structure data. The removal unit 25 deletes the point at the position acquired by the determination unit 24 from one or both of the tree structure data and the point cloud data (step S140).

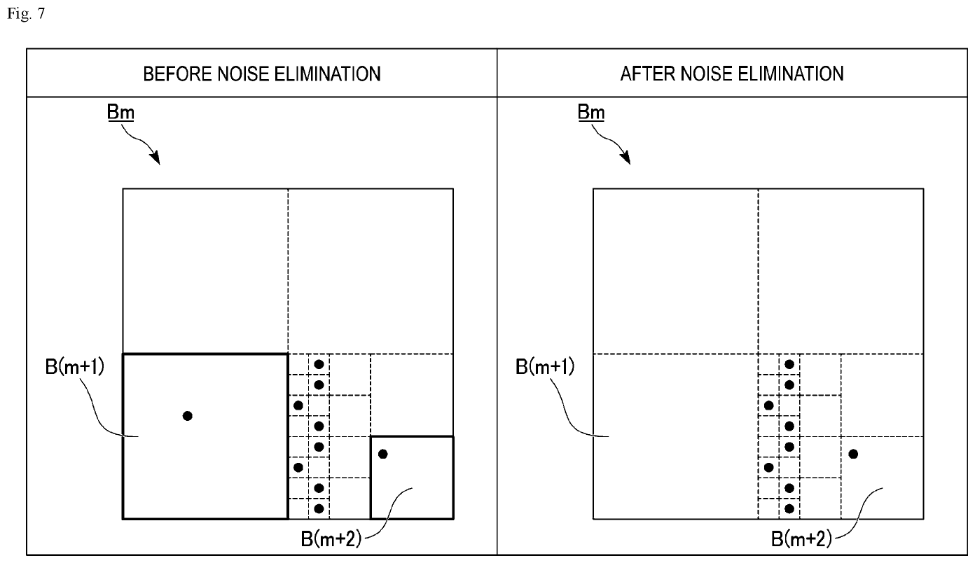

FIG. 7 is a diagram illustrating an example of the noise elimination processing illustrated in FIG. 6. The point cloud before noise elimination illustrated in FIG. 7 is similar to the point cloud before noise elimination illustrated in FIG. 15. Since the block B (m+1) is higher than the N-th layer and the direct mode is selected, the determination unit 24 determines a point included in the block B (m+1) to be noise. On the other hand, since the block B (m+2) is the N-th layer or less, even if the direct mode is selected, the determination unit 24 does not determine a point included in the block B (m+2) to be noise. The removal unit 25 removes a point in the block B (m+1) determined to be noise.

According to the present embodiment, a point that exists in a space having a density lower than that of other points can be determined to be noise.

### Second Embodiment

In the first embodiment, the layer N used as a threshold for determining noise can be optionally set. In the present embodiment, the layer N is selected based on the ratio at which the direct mode is selected in each layer. The present embodiment will be described focusing on differences from the first embodiment. The configuration of a noise determination apparatus of the present embodiment is similar to that of the noise determination apparatus 2 of the first embodiment illustrated in FIG. 2.

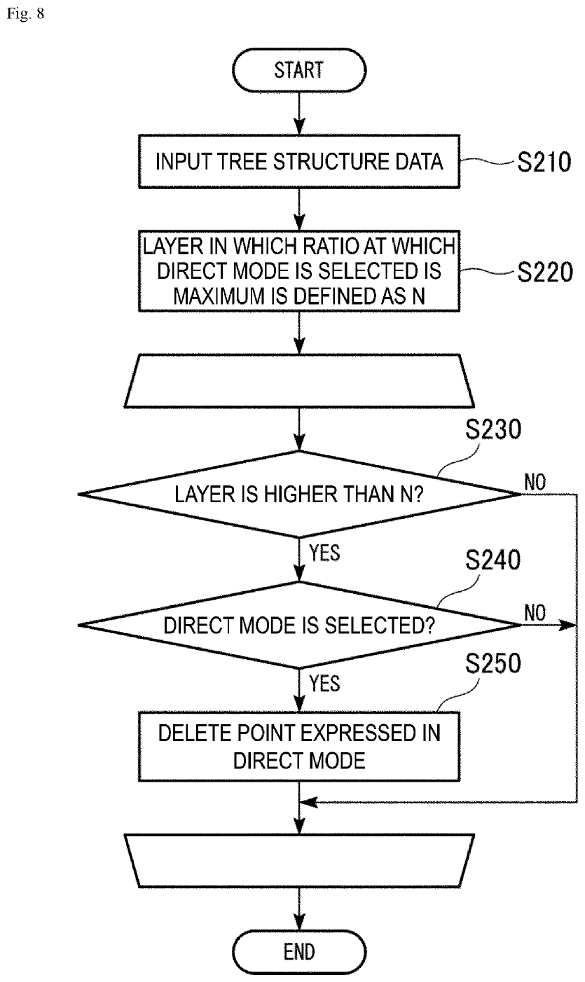

FIG. 8 is a flowchart illustrating noise elimination processing of the noise determination apparatus 2 of the present embodiment. First, the acquisition unit 23 acquires tree structure data of the entire point cloud (step S210). The determination unit 24 calculates the ratio of nodes for which the direct mode is selected for each layer based on the acquired tree structure data. The determination unit 24 defines a layer in which the ratio of nodes for which the direct mode is selected satisfies a predetermined condition as N. Here, the determination unit 24 defines a layer in which the ratio of nodes for which the direct mode is selected is the maximum as N (step S220).

The determination unit 24 performs the processing of steps S230 to S240 on each block generated by dividing the block B0 as a processing target. That is, the determination unit 24 obtains the layer of the block to be processed based on the tree structure data acquired in step S210. The determination unit 24 determines whether or not the layer of the block to be processed is higher than N (step S230). When determining that the layer of the block to be processed is N or less (step S230: NO), the determination unit 24 determines the processing target to be the next block.

When determining that the layer of the block to be processed is higher than N (step S230: YES), the determination unit 24 determines whether or not the direct mode is selected for the block to be processed (step S240). When determining that the direct mode is not selected (step S240: NO), the determination unit 24 determines the processing target to be the next block.

On the other hand, when determining that the direct mode is selected (step S240: YES), the determination unit 24 determines a point included in the block to be processed to be noise. The determination unit 24 acquires information on the position of the point expressed in the direct mode from the tree structure data. The removal unit 25 deletes the point at the position acquired by the determination unit 24 from one or both of the tree structure data and the point cloud data (step S250).

According to the present embodiment, a point existing in a space having a relatively lower density than other points can be determined to be noise.

### Third Embodiment

In the present embodiment, in addition to the determination in the first and second embodiments, when a point included in the block of the direct mode is located closer to the center of the block than a predetermined position, the point is determined to be noise. The present embodiment will be described focusing on differences from the first embodiment. The differences between the present embodiment and the first embodiment may be applied to the second embodiment. The configuration of a noise determination apparatus of the present embodiment is similar to that of the noise determination apparatus 2 of the first embodiment illustrated in FIG. 2.

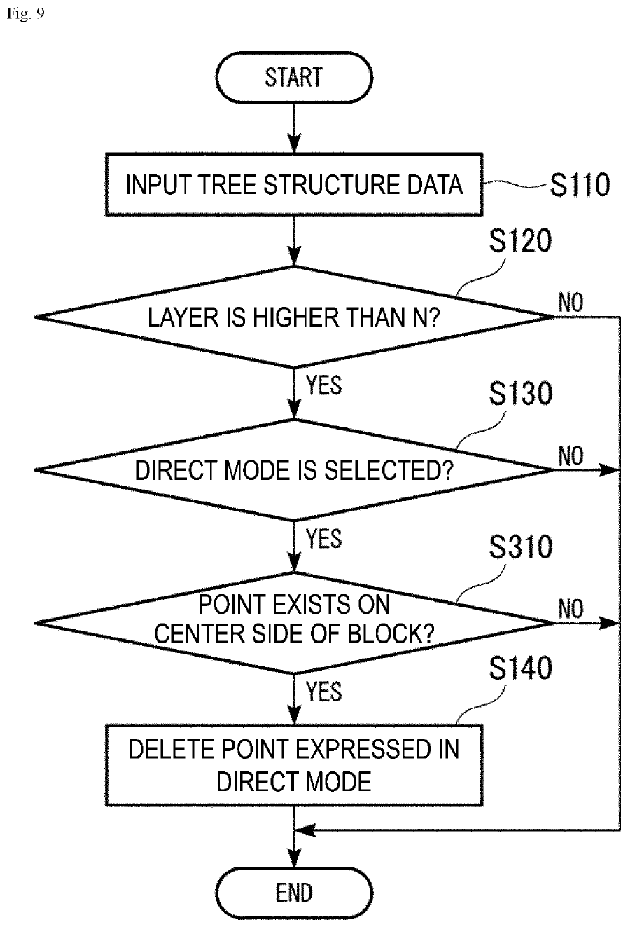

FIG. 9 is a flowchart illustrating noise elimination processing of the noise determination apparatus 2 of the present embodiment. In the drawing, the same reference numerals are assigned to the same processing as the processing flow of the first embodiment illustrated in FIG. 6, and the detailed description thereof will be omitted. The acquisition unit 23 performs the processing illustrated in FIG. 9 for each block generated by dividing the block B0 including the point cloud indicated by the point cloud data.

The noise determination apparatus 2 performs the processing of steps S110 to S130 indicated by the processing flow of FIG. 6. When determining that the layer of the block to be processed is higher than N (step S120: YES) and the direct mode is selected for the block to be processed (step S130: YES), the determination unit 24 performs the processing of step S310.

The determination unit 24 acquires information on the position of the point included in the block to be processed and expressed in the direct mode from the tree structure data. The information on the position of the point is obtained from the block value assigned to the node corresponding to the block to be processed. The determination unit 24 determines whether or not the point exists on the center side of the block to be processed than a predetermined position based on the information on the acquired position (step S310). When determining that the point does not exist on the center side (step S310: NO), the determination unit 24 ends the processing for the block to be processed.

On the other hand, when determining that the point is located on the center side (step S310: YES), the determination unit 24 determines the point included in the block to be processed to be noise. The removal unit 25 deletes the point determined to be noise by the determination unit 24 from one or both of the tree structure data and the point cloud data (step S140).

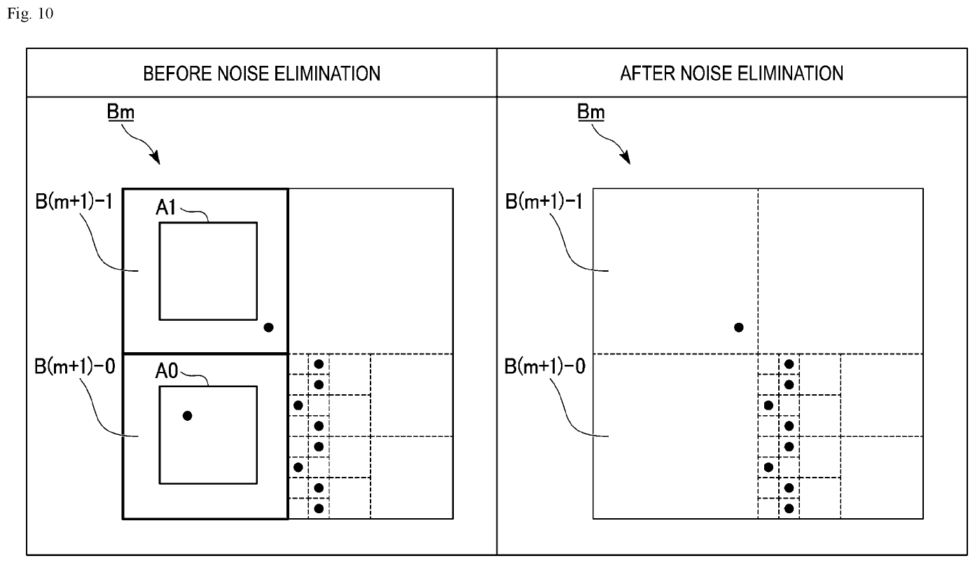

FIG. 10 is a diagram illustrating an example of the noise elimination processing illustrated in FIG. 9. In FIG. 10, for simplicity, each block obtained by dividing the spatial region is represented by a plane. Before noise elimination, the direct mode is selected for the block B (m+1)-0 and the block B (m+1)-1 that are child blocks of the block Bm. The layer (m+1) of the blocks B (m+1)-0 and B (m+1)-1 is higher than N. The determination unit 24 determines the point included in the block B (m+1)-0 to be noise because the point is within a predetermined range A0 from the center of the block B (m+1)-0. On the other hand, since the point included in the block B (m+1)-1 is not within a predetermined range A1 from the center of the block B (m+1)-1, the determination unit 24 determines the point to not be noise. The range A1 and the range A2 have the same size, but may have different sizes. In addition, the size of the range varies depending on the layer.

According to the present embodiment, since a point that exists in a space having a density lower than that of other points and is separated from the other points is determined to be noise, noise can be accurately eliminated.

### Fourth Embodiment

In the present embodiment, in addition to the determination in the above embodiment, when no other points exist around the point expressed in the direct mode, it is determined to be noise. The present embodiment will be described focusing on differences from the first embodiment. The differences between the present embodiment and the first embodiment may be applied to the second embodiment or the third embodiment. The configuration of a noise determination apparatus of the present embodiment is similar to that of the noise determination apparatus 2 of the first embodiment illustrated in FIG. 2.

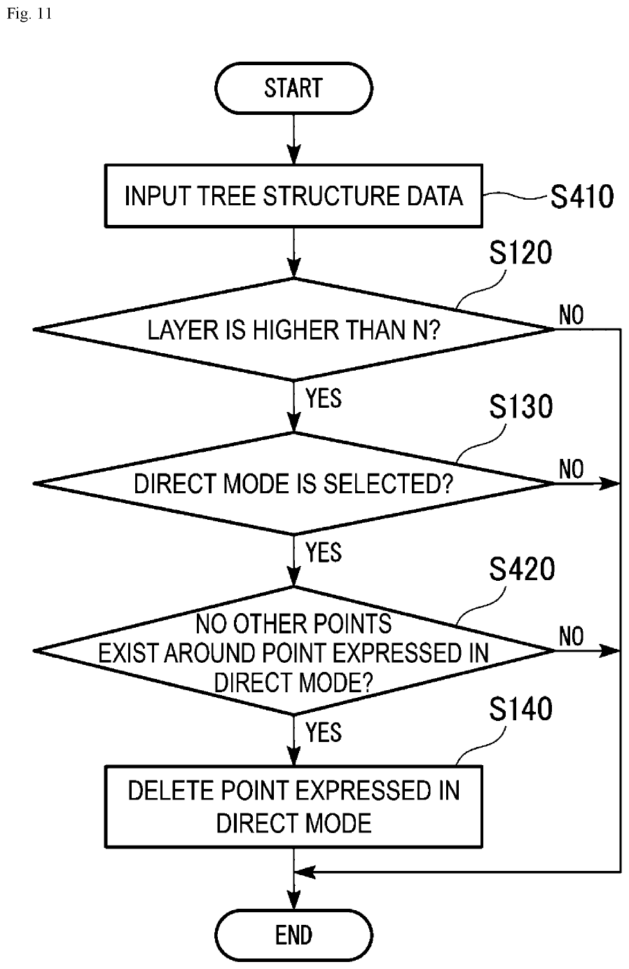

FIG. 11 is a flowchart illustrating noise elimination processing of the noise determination apparatus 2 of the present embodiment. In the drawing, the same reference numerals are assigned to the same processing as the processing flow of the first embodiment illustrated in FIG. 6, and the detailed description thereof will be omitted. The acquisition unit 23 performs the processing illustrated in FIG. 11 for each block generated by dividing the block B0 including the point cloud indicated by the point cloud data.

The acquisition unit 23 acquires tree structure data of the entire point cloud (step S410). Alternatively, the acquisition unit 23 may acquire tree structure data of the block to be processed and tree structure data of blocks around the block to be processed. The noise determination apparatus 2 performs the processing of steps S120 to S130 indicated by the processing flow of FIG. 6. When determining that the layer of the block to be processed is higher than the N-th layer (step S120: YES) and the direct mode is selected for the block to be processed (step S130: YES), the determination unit 24 performs the processing of step S420.

The determination unit 24 determines whether or not no other points exist around the point included in the block to be processed (step S420). Specifically, the determination unit 24 acquires information on the position of the point included in the block to be processed and expressed in the direct mode from the tree structure data. In addition, the determination unit 24 acquires, from the tree structure data, information on the positions of other points in blocks around the block to be processed. The determination unit 24 determines whether or not no other points exist within a predetermined range from the point included in the block to be processed. When determining that another point exists within the predetermined range from the point included in the block to be processed (step S420: NO), the determination unit 24 ends the processing for the block to be processed.

On the other hand, when determining that no other points exist within the predetermined range from the point included in the block to be processed (step S420: YES), the determination unit 24 determines the point included in the block to be processed to be noise. The removal unit 25 deletes the point determined to be noise by the determination unit 24 from one or both of the tree structure data and the point cloud data (step S140).

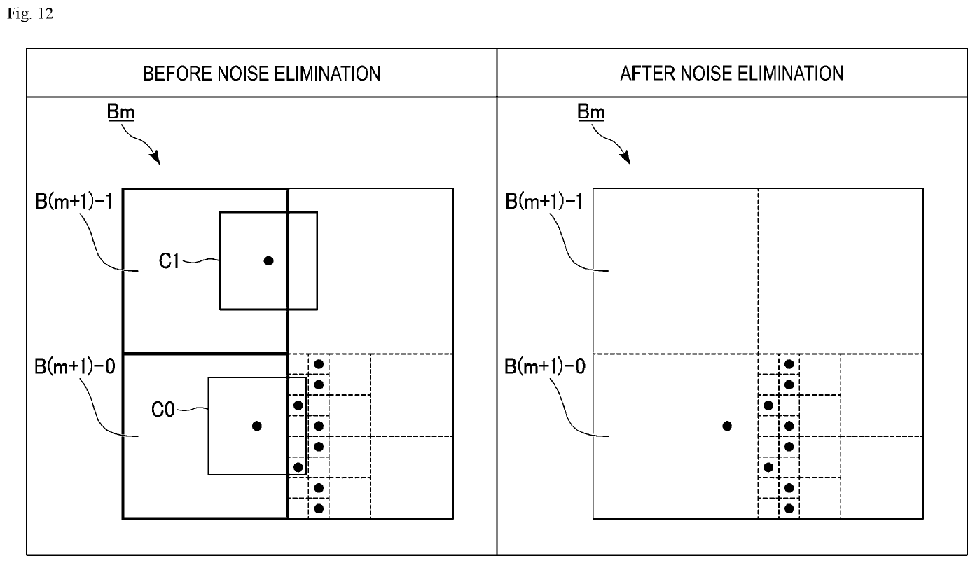

FIG. 12 is a diagram illustrating an example of the noise elimination processing illustrated in FIG. 11. In FIG. 12, for simplicity, each block obtained by dividing the spatial region is represented by a plane. Before noise elimination, the direct mode is selected for the block B (m+1)-0 and the block B (m+1)-1 that are child blocks of the block Bm. The layer (m+1) of the blocks B (m+1)-0 and B (m+1)-1 is higher than N. Since there is another point within a predetermined range C0 from the point included in the block B (m+1)-0, the determination unit 24 determines the point to not be noise. On the other hand, since there is no other points within a predetermined range C1 from the point included in the block B (m+1)-1, the determination unit 24 determines the point to be noise. The range C0 and the range C1 have the same size, but may have different sizes. In addition, the sizes of the ranges may be different or the same depending on the layer. The shape of the range may be a cube or a sphere.

According to the present embodiment, since a point that exists in a space having a density lower than that of other points and is separated from the other points is determined to be noise, noise can be accurately eliminated.

In the above description, the cubic parent block is divided into eight cubic child blocks, but the parent block and the child blocks may not be cubic. For example, in a case where the parent block is divided into n child blocks, n-branch tree structure data in which a spatial region including a point is expressed by an n-branch tree structure is used instead of the tree structure data expressed by the octree structure as described above.

The functions of the noise determination apparatus 2 in the above-described embodiment may be implemented by a computer. In that case, the functions may be implemented by recording a program for implementing the functions in a computer readable recording medium and causing a computer system to read and execute the program recorded in the recording medium. Note that the “computer system” described here is assumed to include an OS and hardware such as a peripheral device. The “computer-readable recording medium” means a portable medium such as a flexible disk, a magneto-optical disk, a ROM, or a CD-ROM or a storage device such as a hard disk incorporated in the computer system. Moreover, the “computer-readable recording medium” may include a recording medium that dynamically holds the program for a short period of time, such as a communication line in a case in which the program is transmitted via a network such as the Internet or a communication line such as a telephone line, or a recording medium that holds the program for a specific period of time, such as a volatile memory inside a computer system that serves as a server or a client in that case. Further, the program may be for implementing some of the functions described above, and the functions described above may be implemented by a combination of the above-described functions and the program already recorded in the computer system.

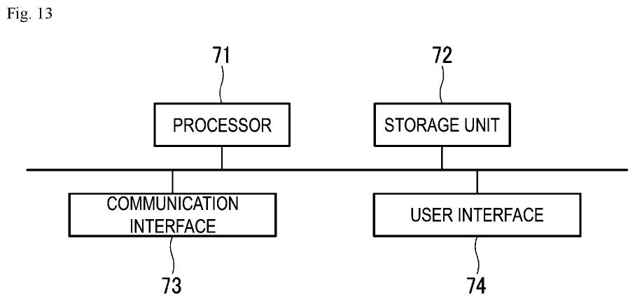

A hardware configuration example of the noise determination apparatus 2 will be described. FIG. 13 is an apparatus configuration diagram illustrating a hardware configuration example of the noise determination apparatus 2. The noise determination apparatus 2 includes a processor 71, a storage unit 72, a communication interface 73, and a user interface 74.

The processor 71 is a central processing device that performs operation and control. The processor 71 is, for example, a CPU. The processor 71 loads and executes a program from the storage unit 72. The storage unit 72 further includes a work area for the processor 71 to execute various programs and the like. The communication interface 73 is communicatively connected to other apparatuses. The user interface 74 is an input device such as a keyboard, a pointing device (mouse, tablet, etc.), a button, or a touch panel, or a display device such as a display. An artificial operation is input by the user interface 74. For example, information of the layer N used as a threshold is input through the user interface 74.

The functions of the encoding unit 22, the acquisition unit 23, the determination unit 24, and the removal unit 25 are implemented by the processor 71 reading and executing a program from the storage unit 72. All or some of these functions may be implemented by using hardware such as an application specific integrated circuit (ASIC), a programmable logic device (PLD), or a field programmable gate array (FPGA). Furthermore, the storage unit 21 is implemented by the storage unit 72.

The noise determination apparatus 2 may be implemented by a plurality of computer devices connected to a network. In this case, which one of the plurality of computer devices is used to implement each of the functional units of the noise determination apparatus 2 can be freely selected. In addition, the same functional units may be implemented by a plurality of computer devices.

According to the above-described embodiment, the noise determination apparatus includes the acquisition unit and the determination unit. The acquisition unit acquires n-branch tree structure data. The n-branch tree structure data includes information on the presence or absence of a point for each divided region obtained by dividing a spatial region represented by point cloud data including information on the position of each point by an n-branch tree structure including a plurality of layers, and for a divided region including only one point, including a sign representing the point instead of information on a divided region in a layer lower than the divided region. This sign is obtained by encoding information indicating the position of the point by, for example, a coordinate value or the like. The determination unit determines a point represented by a sign in a layer higher than a predetermined layer to be noise.

The determination unit may select a layer in which a ratio of signs representing a point satisfies a predetermined condition in the n-branch tree structure data, and determine a point represented by the above sign to be noise in a layer higher than the selected layer. For example, the predetermined condition is that the ratio of signs representing a point is the largest.

Furthermore, in a case where the point represented by the above-described sign is located within a predetermined range from the center of the divided region including the point, the determination unit may determine the point to be noise. Furthermore, in a case where no other points exist within a predetermined range from the point represented by the above-described sign, the determination unit may determine the point to be noise.

According to the above-described embodiment, it is possible to accurately determine and eliminate noise included in the point cloud data.

Although embodiments of the present invention have been described above in detail with reference to the drawings, the specific configurations thereof are not limited to those of the embodiments and also include designs or the like without departing from the spirit of the present invention.

### REFERENCE SIGNS LIST

2 Noise determination apparatus
11 Moving body
12 LIDAR
13 Memory
14 Measurement DB
15 Three-dimensional DB
16 Information processing apparatus
17 Analysis apparatus
18 Three-dimensional structure DB
19 Terminal device
21 Storage unit
22 Encoding unit
23 Acquisition unit
24 Determination unit
25 Removal unit
71 Processor
72 Storage unit
73 Communication interface
74 User interface

1. A noise determination method, comprising:
acquiring n-branch tree structure data,
the n-branch tree structure data
including information on presence or absence of a point for a divided region obtained by dividing, by an n-branch tree structure including a plurality of layers, a spatial region represented by point cloud data including information on a position of a point, and
including, for the divided region including only one point, a sign representing the point instead of information on a divided region of a layer lower than the divided region; and
determining a point represented by the sign to be noise in a layer higher than a predetermined layer.

2. The noise determination method according to claim 1, further comprising selecting a layer in which a ratio of a plurality of the signs each representing a point in the n-branch tree structure data satisfies a predetermined condition,
wherein, in the step of determining, a point represented by the sign is determined to be noise in a layer higher than the layer selected in the step of selecting.

3. The noise determination method according to claim 2, wherein the predetermined condition is a condition that the ratio is a largest ratio.

4. The noise determination method according to claim 1, wherein, in the step of determining, when a point represented by the sign is located within a predetermined range from a center of the divided region including the point, the point is determined to be noise.

5. The noise determination method according to claim 1, wherein, in the step of determining, when no other points exist within a predetermined range from a point represented by the sign, the point is determined to be noise.

6. The noise determination method according to claim 1, wherein the sign represents a coordinate value of the point.

7. A noise determination apparatus, comprising:
an acquisition unit configured to acquire n-branch tree structure data,
the n-branch tree structure data
including information on presence or absence of a point for a divided region obtained by dividing, by an n-branch tree structure including a plurality of layers, a spatial region represented by point cloud data including information on a position of a point, and
including, for the divided region including only one point, a sign representing the point instead of information on a divided region of a layer lower than the divided region; and
a determination unit configured to determine a point represented by the sign to be noise in a layer higher than a predetermined layer.

8. A non-transitory computer-readable medium having computer-executable instructions that, upon execution of the instructions by a processor of a computer, cause the computer to function as the noise determination method according to claim 1.
